(19) United States
(12) Patent Application Publication
(10) Pub. No.: US 2024/0387145 A1
(43) Pub. Date: Nov. 21, 2024

(54) ONE SIDE ANODIZATION OF DIFFUSER

(71) Applicant: Applied Materials, Inc., Santa Clara, CA (US)

(72) Inventors: Jong Yun Kim, Gyeonggi-do (KR); William Nehrer, Soquel, CA (US); Sang Jeong Oh, Santa Clara, CA (US); Ying Ma, Castro Valley, CA (US)

(73) Assignee: Applied Materials, Inc., Santa Clara, CA (US)

(21) Appl. No.: 18/692,954

(22) PCT Filed: Sep. 17, 2021
(86) PCT No.: PCT/US2021/050861

§ 371 Date: Mar. 18, 2024

(51) Int. Cl. H01J 37/32; C25D 11/02

(52) U.S. Cl. CPC H01J 37/3244; C25D 11/02; H01J 2237/332

(57) ABSTRACT

Exemplary diffusers for a substrate processing chamber may include a diffuser body that is characterized by a first surface on an inlet side of the diffuser body and a second surface on an outlet side of the diffuser body. The diffuser body may define a plurality of apertures through a thickness of the diffuser body. The first surface may not be anodized. The second surface may be anodized.

### TECHNICAL FIELD

The present technology relates to components and apparatuses for glass substrate and semiconductor substrate manufacturing. More specifically, the present technology relates to processing chamber distribution components and other substrate processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features, such as apertures, for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

Exemplary diffusers for substrate processing chambers may include a diffuser body that is characterized by a first surface on an inlet side of the diffuser body and a second surface on an outlet side of the diffuser body. The diffuser body may define a plurality of apertures through a thickness of the diffuser body. The first surface may be un-anodized. The second surface may be anodized.

In some embodiments, each of the plurality of apertures may include an upper region and a lower region. The upper region and the lower region may be separated by a choke region. The choke region may be anodized. The choke region may be un-anodized. The lower region may be anodized. The lower region may include a generally conical shape. The diffuser may include a lateral surface that extends between and couples the first surface and the second surface. The lateral surface may be un-anodized.

Some embodiments of the present technology may encompass methods of anodizing one surface of a diffuser. The methods may include coating a first surface of a diffuser with a polymeric material while leaving a second surface of the diffuser exposed. The first surface may be opposite the second surface. The diffuser may define a plurality of apertures through a thickness of the diffuser. The methods may include applying heat to the diffuser. The methods may include exposing the diffuser to a chemical bath. The methods may include applying voltage to the chemical bath to anodize the second surface of the diffuser. The methods may include removing the polymeric material from the first surface.

In some embodiments, the methods may include flowing a pressurized material through the apertures after applying heat to the diffuser. Flowing the pressurized material may include one or both of bead blasting and CO₂ blasting. Each of the plurality of apertures may include an upper region and a lower region. The upper region and the lower region may be separated by a choke region. Flowing the pressurized material may remove any polymeric material that is present in the choke region of each of the plurality of apertures. Coating the first surface may include using a directional coating process to apply the polymeric material onto the first surface and into a portion of each of the plurality of apertures at an angle relative to a length of each of the plurality of apertures. Removing the polymeric material may include applying heat to the polymeric material to soften the polymeric material. Removing the polymeric material may include peeling the polymeric material from the diffuser. Removing the polymeric material may include exposing the diffuser to a solvent. Applying voltage to the chemical bath may include ramping up the voltage from a starting voltage to target voltage. Applying voltage to the chemical bath may include maintaining the voltage at the target voltage for a predetermined period of time. Applying voltage to the chemical bath may include ramping up the voltage from the target voltage to an additional target voltage. Applying voltage to the chemical bath may include maintaining the voltage at the additional target voltage for an additional predetermined period of time. The diffuser may include a lateral surface that extends between and couples the first surface and the second surface. The method may include coating the lateral surface with the polymeric material.

Some embodiments of the present technology may encompass methods of processing a substrate. The methods may include flowing a precursor into a processing chamber. The processing chamber may include a diffuser and a substrate support on which a substrate is disposed. A processing region of the processing chamber may be at least partially defined between the diffuser and the substrate support. The diffuser may be characterized by a first surface and a second surface facing the substrate support and being opposite the first surface. The diffuser may define a plurality of apertures through a thickness of the diffuser. The first surface may be un-anodized. The second surface may be anodized. The methods may include generating a plasma of the precursor within the processing region of the processing chamber. The methods may include depositing a material on the substrate.

In some embodiments, each of the plurality of apertures may include an upper region and a lower region. The upper region and the lower region may be separated by a choke region. The choke region may be un-anodized. The lower region may include a generally conical shape.

Such technology may provide numerous benefits over conventional systems and techniques. For example, embodiments of the present technology may reduce the impurity content in film and improve the threshold voltage of the wafer. Additionally, the components may maintain desired stability from processing run to processing run. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary diffuser according to some embodiments of the present technology.

FIG. 4 shows operations of an exemplary method of anodizing one surface of a diffuser according to some embodiments of the present technology.

FIGS. 5A-5E illustrate a schematic partial cross-sectional view of an exemplary diffuser being anodized according to some embodiments of the present technology.

FIG. 6 shows operations of an exemplary method of anodizing a diffuser according to some embodiments of the present technology.

FIG. 7 shows operations of an exemplary method of substrate processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop substrate structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. The precursors may be distributed through one or more components within the chamber, which may produce a radial or lateral distribution of delivery to provide increased formation or removal at the substrate surface.

As device features reduce in size, tolerances across a substrate surface may be reduced, and material property differences across a film may affect device realization and uniformity. Many chambers include a characteristic process signature, which may produce non-uniformity across a substrate. Temperature differences, flow pattern uniformity, and other aspects of processing may impact the films on the substrate, creating film uniformity differences across the substrate for materials produced or removed. For example, one or more devices may be included within a processing chamber for delivering and distributing precursors within a processing chamber. A blocker plate may be included in a chamber to provide a choke in precursor flow, which may increase residence time at the blocker plate and lateral or radial distribution of precursors. A faceplate or diffuser may further improve uniformity of delivery into a processing region, which may improve deposition or etching.

Some conventional diffusers have either bare (un-anodized) surfaces, however such diffusers may exhibit poor run-to-run stability for deposition rate and thickness uniformity during deposition processes. To address this instability, some diffusers may be anodized, which may improve the run-to-run stability for deposition rate and thickness uniformity due to the dielectric effect attributed to the anodization of the diffuser. However, during the anodization of the diffuser, nano-sized pores are generated in the oxide film that enable the oxide to grow thicker than passivating conditions would allow. The pores on the bottom of the diffuser may be covered by seasoning films and deposition films and may have no effect on the wafer. However, the pores on the top of the diffuser may remain exposed and may trap some process gases, which may later be released during subsequent deposition operations. These released gases may cause doping of undesired materials onto a wafer, which may negatively affect the threshold voltage of the wafer and/or cause other defects.

The present technology overcomes these challenges by utilizing a diffuser that is only anodized on a bottom surface, while the top surface remains un-anodized. Such a diffuser may eliminate the exposed pores on the top surface though would otherwise trap gas that may later be released to form undesired dopants on the film. As a result, the anodized top surface may improve run-to-run stability for deposition rate and thickness uniformity during deposition processes while maintaining a threshold voltage of the wafer within specifications. Additionally, some embodiments of the present technology may utilize anodization techniques that increase the pore size and reduce the number of pores present on anodized diffuser surfaces to help reduce or eliminate any trapped gas that may later form undesired dopants on the film and impact threshold voltage. Accordingly, the present technology may produce improved film deposition characteristics from wafer to wafer.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

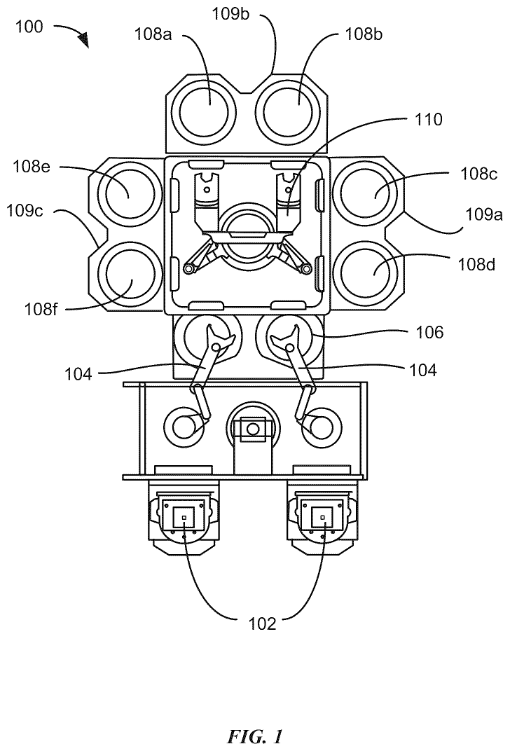

FIG. 1 shows a top plan view of one embodiment of a processing system 100 of deposition, etching, baking, and curing chambers according to embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

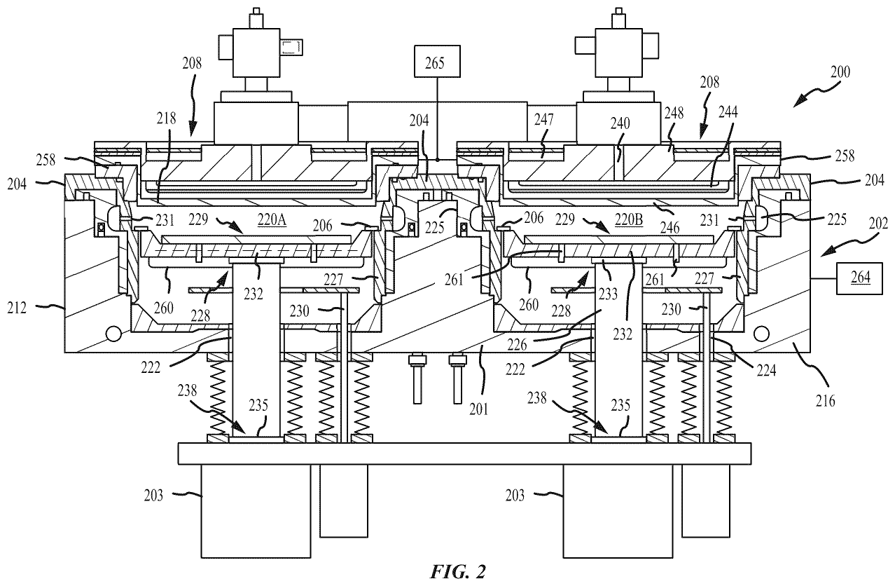

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology as further described below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

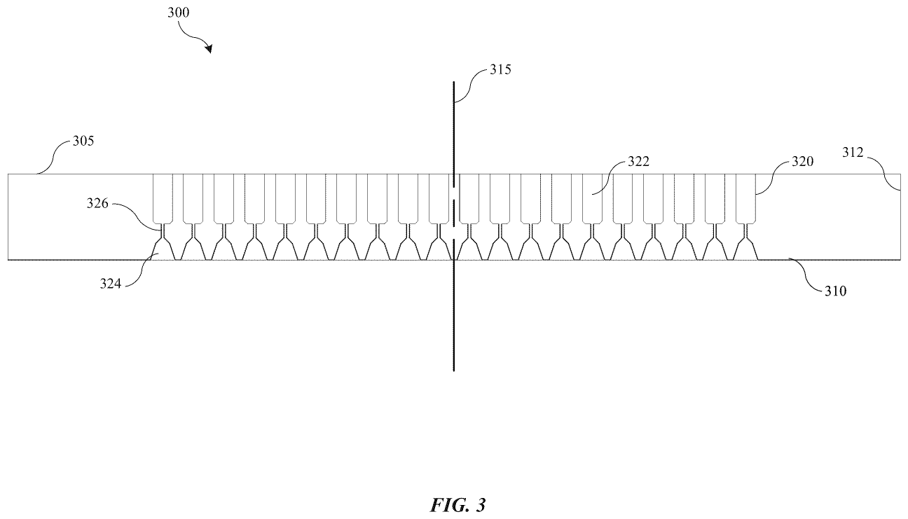

FIG. 3 shows a schematic partial cross-sectional view of an exemplary faceplate or diffuser 300 according to some embodiments of the present technology. FIG. 3 may illustrate further details relating to components in system 200, such as for faceplate 246. Diffuser 300 is understood to include any feature or aspect of system 200 discussed previously in some embodiments. The diffuser 300 may be used to perform substrate processing operations including deposition of hardmask materials as previously described, as well as other deposition, removal, and cleaning operations. For example, in some embodiments, the diffuser 300 may be used to deposit materials on one or more surfaces of a substrate, such as glass substrate and/or semiconductor substrates, such as substrates used in display devices. Diffuser 300 may show a partial view of a diffuser that may be incorporated in a substrate processing system, and may illustrate a view across a center of the diffuser, which may otherwise be of any size, and include any number of apertures. Although shown with a number of apertures extending outward laterally or radially, it is to be understood that the figure is included only for illustration of embodiments, and is not considered to be of scale. For example, exemplary faceplates may be characterized by a number of apertures along a central diameter of greater than or about 20 apertures as will be described further below, and may be characterized by greater than or about 25 apertures, greater than or about 30 apertures, greater than or about 35 apertures, greater than or about 40 apertures, greater than or about 45 apertures, greater than or about 50 apertures, or more.

As noted, diffuser 300 may be included in any number of processing chambers, including system 200 described above. Diffuser 300 may be included as part of the gas inlet assembly, such as with a gasbox and blocker plate. For example, a gasbox may define or provide access into a processing chamber. A substrate support may be included within the chamber, and may be configured to support a substrate for processing. A blocker plate may be included in the chamber between the gasbox and the substrate support. The blocker plate may include or define a number of apertures through the plate. In some embodiments the blocker plate may be characterized by increased central conductance. For example, in some embodiments a subset of apertures proximate or extending about a central region of the blocker plate may be characterized by a greater aperture diameter than apertures radially outward of the central region. This may increase a central flow conductance in some embodiments. The components may include any of the features described previously for similar components, as well as a variety of other modifications similarly encompassed by the present technology.

Diffuser 300 may be positioned within the chamber between the blocker plate and the substrate support as illustrated previously. Diffuser 300 may be characterized by a body having a first surface 305 and a second surface 310, which may be opposite the first surface. In some embodiments, first surface 305 may be on an inlet side of the diffuser 300 and may face towards a blocker plate, gasbox, or gas inlet into the processing chamber. Second surface 310 may be on an outlet side of the diffuser 300 and may be positioned to face a substrate support or substrate within a processing region of a processing chamber. For example, in some embodiments, the second surface 310 of the diffuser 300 and the substrate support may at least partially define a processing region within the chamber. Diffuser 300 may be characterized by a central axis 315, which may extend vertically through a midpoint of the faceplate, and may be coaxial with a central axis through the processing chamber.

Diffuser 300 may define a plurality of apertures 320 defined through the faceplate and extending from the first surface through the second surface. Each aperture 320 may provide a fluid path through the faceplate, and the apertures may provide fluid access to the processing region of the chamber. Depending on the size of the diffuser, and the size of the apertures, diffuser 300 may define any number of apertures through the plate, such as greater than or about 1,000 apertures, greater than or about 2,000 apertures, greater than or about 3,000 apertures, greater than or about 4,000 apertures, greater than or about 5,000 apertures, greater than or about 6,000 apertures, or more. As noted above, the apertures may be included in a set of rings extending outward from the central axis, and may include any number of rings as described previously. The rings may be characterized by any number of shapes including circular or elliptical, as well as any other geometric pattern, such as rectangular, hexagonal, or any other geometric pattern that may include apertures distributed in a radially outward number of rings. The apertures may have a uniform or staggered spacing, and may be spaced apart at less than or about 10 mm from center to center. The apertures may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, apertures may be characterized by a scaling function of apertures per ring. For example, in some embodiments a first aperture may extend through a center of the diffuser, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number, as will be described further below where the first ring has an augmented number of apertures. For example, for an exemplary diffuser having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 50 rings. In some embodiments each aperture of the plurality of apertures across the diffuser may be characterized by an aperture profile, which may be the same or different in embodiments of the present technology.

The apertures 320 may include any profile or number of sections having different profiles, such as illustrated. For example, in some embodiments the apertures 320 may be generally cylindrical. In other embodiments, some or all of the apertures 320 may have more complex profiles. For example, in one non-limiting example as illustrated, each aperture 320 may include an upper region 322 and a lower region 324. The upper region 322 and the lower region 324 may be separated by a choke region 326, which may have a smaller diameter (or average diameter) than the upper region 322 and the lower region 324. The upper region 322 may extend from the first surface 305 of the diffuser 300, and may extend partially through the diffuser 300. In some embodiments, the upper region 322 may extend at least about or greater than halfway, or 75% of the way through a thickness of the diffuser between first surface 305 and second surface 310. Upper region 322 may be characterized by a substantially cylindrical profile as illustrated. By substantially is meant that the profile may be characterized by a cylindrical profile, but may account for machining tolerances and parts variations, as well as a certain margin of error. The upper region 322 may transition to an optional choke region 326, which may operate as a choke in the diffuser 300, and may increase distribution or uniformity of flow. As illustrated, the choke region 326 may include a taper and/or step that transitions from a diameter of the upper region 322 to a narrower diameter of the choke region 326. A diameter of the choke region 326 may be less than a diameter of the upper region 322. For example, the diameter of the upper region 322 may be more than 1.5×, more than 1.75×, more than 2.0×, more than 2.25×, more than 2.5×, or greater than the diameter of the choke region 326. The choke region 326 may then flare to lower region 324. Lower region 324 may extend from a position partially through the diffuser to the second surface 310. Lower region 324 may extend less than halfway through the thickness of the diffuser 300, for example, or may extend up to or about halfway through the diffuser 300. Lower region 324 may be characterized by a tapered profile from the second surface 310 in some embodiments, and may extend to include a cylindrical and/or conical portion intersecting choke region 326, when included. Lower region 324 may be characterized by a generally conical profile in some embodiments, or may be characterized by a countersunk profile, among other tapered profiles. In some embodiments, the generally conical profile may include a single tapered/conical region, while in other embodiments the generally conical profile may include two or more regions of different degrees of taper as illustrated. A maximum diameter of the lower region 324 (such as at second surface 310) may be greater than a diameter of both the upper region 322 and the choke region 326. For example, the maximum diameter of the lower region 324 may be more than 1.1×, more than 1.2×, more than 1.3×, more than 1.4×, more than 1.5×, more than 1.75×, more than 2.0×, more than 2.25×, more than 2.5×, or greater than the diameter of the upper region 322. The maximum diameter of the lower region 324 may be more than 3.5×, more than 4.0×, more than 4.5×, more than 5.0×, more than 5.25×, or greater than the diameter of the choke region 326.

The conical profile of the lower region 324 of the apertures 320 may help increase the ion flux due to a pronounced hollow cathode effect in conical sections. This increased ion flux translates directly into a deposition rate improvement at edges of a substrate positioned beneath the diffuser. The increased deposition at the edges of the substrate result in an overall increase in uniformity of deposition and a flatter thickness profile across the substrate.

A portion of the diffuser 300 may be anodized. For example, the second surface 310 of the diffuser 300 may be anodized, while the first surface 305 (and at least the upper region 322 of each apertures 320) is un-anodized. This may enable the diffuser to provide the benefits of both bare and anodized diffusers without any of the drawbacks. In particular, the anodized second surface 310 may improve run-to-run stability for deposition rate and thickness uniformity during deposition processes while eliminating nano-pore formation on the first surface 305 that may negatively impact a threshold voltage of the wafer. In some embodiments, along with second surface 310, the lower region 324 and/or choke region 326 of each of the apertures 320 may be anodized, while in other embodiments the lower region 324 and/or choke region 326 of each of the apertures 320 may be un-anodized. In embodiments in which the choke region 326 is anodized, the anodization process may be carefully controlled to ensure uniform anodization within each aperture 320 and to keep a diameter of each choke region 326 uniform and at a desired size to maintain proper and uniform flow conductance through the diffuser 300. The diffuser 300 may include a lateral surface 312 that extends between and couples the first surface 305 and the second surface 310. In some embodiments, the lateral surface 312 may be anodized, while in other embodiments the lateral surface 312 may be un-anodized.

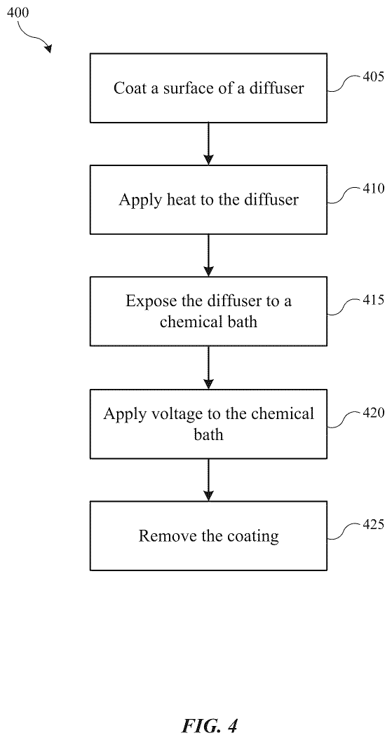

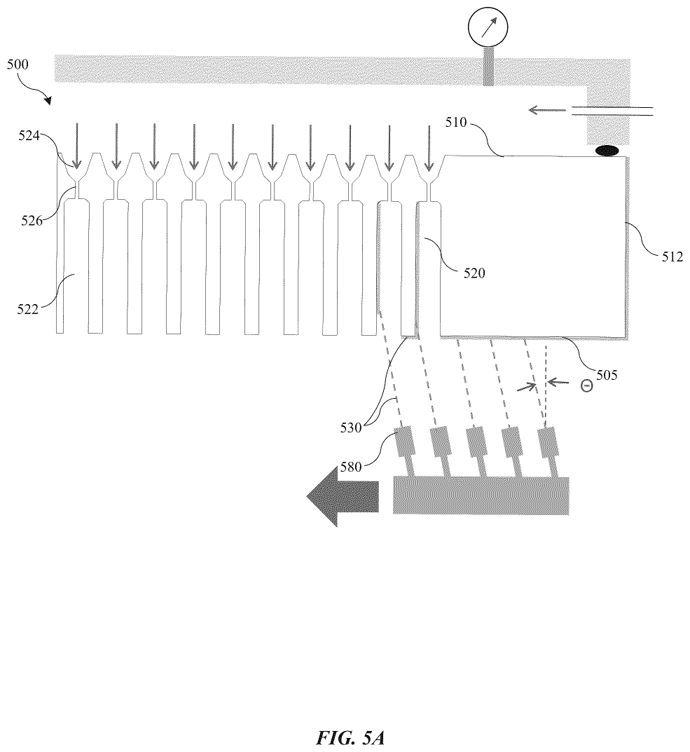

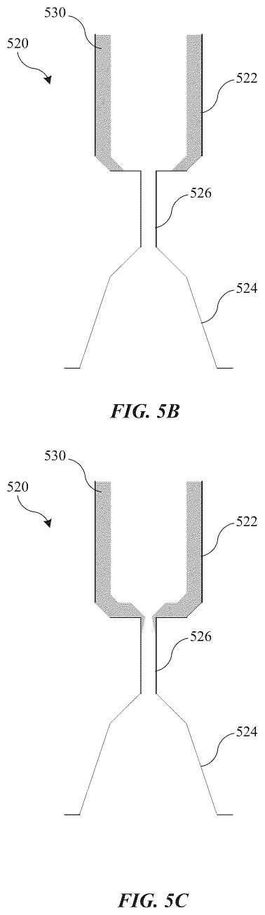

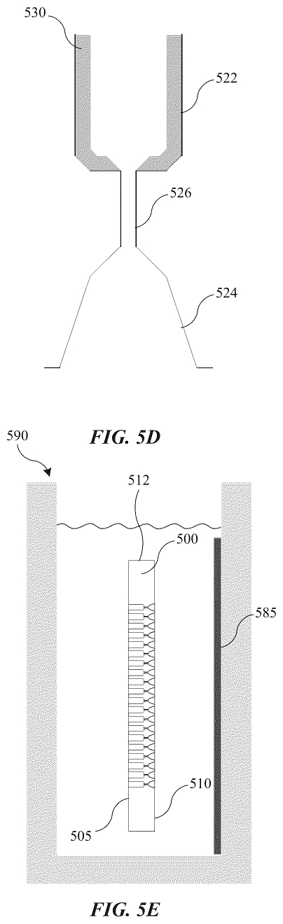

FIG. 4 shows operations of an exemplary method 400 of anodizing one surface of a diffuser according to some embodiments of the present technology. The method may produce a diffuser having a single anodized surface similar to diffuser 300 described above. Method 400 may include a number of optional operations, which may or may not be specifically associated with some embodiments of methods according to the present technology. Method 400 may include optional operations prior to initiation of method 400, or the method may include additional operations. For example, method 400 may include operations performed in different orders than illustrated. Method 400 will be described in conjunction with FIGS. 5A-5E, which illustrate a diffuser 500 (which may be similar to diffuser 300 and may be used in any processing chamber, such as processing chamber 200) being anodized according to method 400.

In some embodiments, method 400 may include coating a first surface 505 of diffuser 500 with a polymeric material 530 while leaving a second surface 510 of the diffuser 500 exposed at operation 405. Along with the first surface 510, a portion of each aperture 520 defined by the diffuser 500 may be coated. For example, an upper region 522 of each aperture 520 may be coated with the polymeric material 530. The first surface 505 may be similar to first surface 305 and may be a top surface of the diffuser 500, while the second surface 510 may be similar to second surface 310 and may be a lower surface of the diffuser 500. In some embodiments, a lateral surface 512 may be coated with the polymeric material 530. The polymeric material 530 may include a thermoplastic material (such as, but not limited to, high density polyethylene, polyurethane, polyethylene terephthalate, etc.) in some embodiments, which may protect the coated surface of the diffuser 500 from being anodized. In some embodiments, such as illustrated in FIG. 5A, coating the first surface 505 may include a directional coating application process such as, but not limited to, 3D printing and/or spraying the polymeric material 530 onto the first surface 505 and into the upper region 522 of each aperture 520. It may be desirable to prevent the polymeric material 530 from entering a choke region 526 of the apertures 520. In some embodiments to help prevent this, one or more applicator nozzles 580 used to apply the polymeric material 530 may be angled relative to a longitudinal axis of each aperture 520 such that polymeric material emitted from the nozzle 580 is not directed at the choke region 526. For example, the nozzles 580 may be angled such that an edge of the emitted polymeric material is aimed at a bottom corner and/or edge of the upper region 522. This angle may depend on the aspect ratio of the upper region 522 of the apertures 520. The nozzles 580 may be translated horizontally along one or more directions and/or rotated in one or more passes over the diffuser 500 to uniformly coat the desired surfaces of the diffuser 500. In some embodiments, the diffuser 500 may be inverted during the coating process such that the first surface 505 faces downward. Such an orientation may help prevent the polymeric material 530 from flowing into the choke region 526 of each aperture 520 due to the effects of gravity. Additionally or alternatively, air (or other fluid) may be flowed through the lower region 524 and choke region 526 of each aperture 520 during the coating operation. For example, the second surface 510 of the diffuser 500 may be capped or otherwise sealed off, with a fluid source supplying a fluid to create a positive pressure environment proximate the second surface 510. The positive pressure may generate an airflow through the apertures 520, and in particular through the choke region 526, that is sufficiently high to prevent the polymeric material 530 from penetrating the choke region 526 without disrupting the spray from reaching the base of the upper region 522 of the apertures 520.

As illustrated in FIG. 5B, coating the first surface 505 may result in the polymeric material 530 not fully reaching a base of the upper region 522. For example, the airflow through the choke region 526 and/or the angle of the spray from the nozzle 580 may result in some or all of the base of the upper region 522 of each aperture 520 remaining uncoated. At operation 410, heat may be applied to the diffuser 500, which may soften the polymeric material 530 sufficiently so as to flow and cover the base of the upper region 522. The heat may be applied to a softening temperature of the polymeric material 530. In some embodiments, the softening temperature may be between or about 100° C. and 150° C., although it will be appreciated that such temperature may be dependent on the polymeric material used. In some instances, some of the polymeric material 530 may flow into the choke region 526 as illustrated in FIG. 5C, which may lead to non-uniformity in the choke region 526 during anodization. To eliminate this issue, the method may include flowing a pressurized material through the apertures after applying heat to the diffuser. For example, bead blasting, CO₂ blasting, sand blasting, and/or other technique for delivering a pressurized material may be used to remove any polymeric material 530 from the choke region 526 as illustrated in FIG. 5D. The pressurized material may be delivered from the second surface 510 side of the diffuser 500 so as to prevent the pressurized material from removing any material within the upper region 522 and/or first surface 505.

The partially coated diffuser 500 may be exposed to a chemical bath 590 at operation 415. For example, the diffuser 500 may be submerged in an electrolyte, with the second surface 510 facing a cathode 585 as illustrated in FIG. 5E. A voltage may be applied to the chemical bath at operation 420 to anodize the exposed second surface 510, while the coated first surface 505 remains un-anodized. In some embodiments, the voltage may be ramped up from a starting voltage (which may be zero) to a target voltage. The voltage may be maintained at the target voltage for a predetermined period of time. The target voltage may be a final voltage in some embodiments. By using a single target voltage step, pore sizes may be increased and pore density may be decreased on any anodized surfaces, which may reduce the amount of gas that may be trapped and subsequently released by the pores during deposition operations. Additionally, fewer pore branches are generated as compared to multi-step voltage delivery processes. This may help improve threshold voltage consistency in wafers produced using the diffuser. In other embodiments, the target voltage may be an intermediate voltage. In such embodiments, the voltage may be ramped up from the target voltage to an additional, higher target voltage, which may be maintained for an additional predetermined period of time. Such steps may be repeated any number of times to complete the anodization process. For example, three target voltages may be used in some embodiments, although the process may include one or more target voltages, two or more target voltages, three or more target voltages, four or more target voltages, five or more target voltages, ten or more target voltages, or more in various embodiments.

Once the second surface 510 has been anodized, the polymeric material 530 may be removed from any coated surfaces at operation 425. Removing the polymeric material 530 may include applying heat to the polymeric material 530 to soften the polymeric material 530. Once softened, the polymeric material 530 may be peeled and/or otherwise manually removed from the surface of the diffuser 500. In some embodiments, some residue of the polymeric material 530 may remain. In such instances, the diffuser 500 may be exposed to a solvent, such as acetone, to remove the residue. The resultant diffuser 500 may be anodized on surfaces that were not coated with the polymeric material 530, while those coated surfaces remain un-anodized. Such a diffuser 500 may provide the benefits of bare and anodized diffusers without any of the drawbacks. In particular, the anodized second surface 510 may improve run-to-run stability for deposition rate and thickness uniformity during deposition processes while eliminating nano-pore formation on the first surface 505 that may negatively impact a threshold voltage of the wafer.

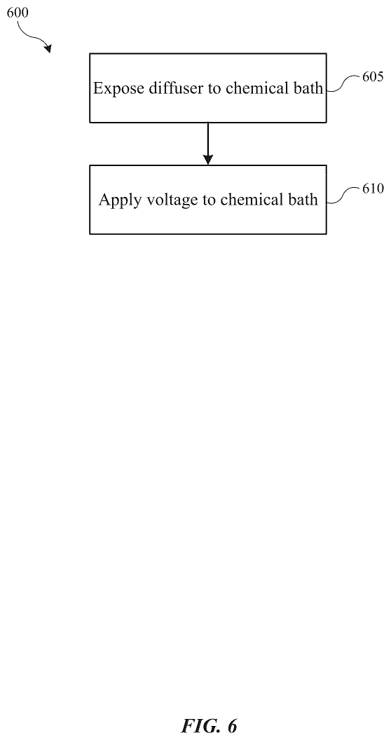

FIG. 6 shows operations of an exemplary method 600 of anodizing a diffuser according to some embodiments of the present technology. The method may produce a diffuser having a single anodized surface similar to diffuser 300 described above, or may produce a diffuser that is fully anodized. Method 600 may include a number of optional operations, which may or may not be specifically associated with some embodiments of methods according to the present technology. Method 600 may include optional operations prior to initiation of method 600, or the method may include additional operations. For example, method 600 may include operations performed in different orders than illustrated.

Method 600 may include exposing a diffuser (which may or may not include any polymeric material coating on any surfaces) to a chemical bath at operation 605. A voltage may be applied to the chemical bath at operation 610 to anodize the exposed (uncoated) surfaces of the diffuser. The voltage may be ramped up from a starting voltage (which may be zero) to a final target voltage in a single step. The voltage may be maintained at the final target voltage for a predetermined period of time. By using a single target voltage step, pore sizes may be increased and pore density may be decreased on any anodized surfaces, which may reduce the amount of gas that may be trapped and subsequently released by the pores during deposition operations. Additionally, fewer pore branches are generated as compared to multi-step voltage delivery processes. This may help improve threshold voltage consistency in wafers produced using the diffuser.

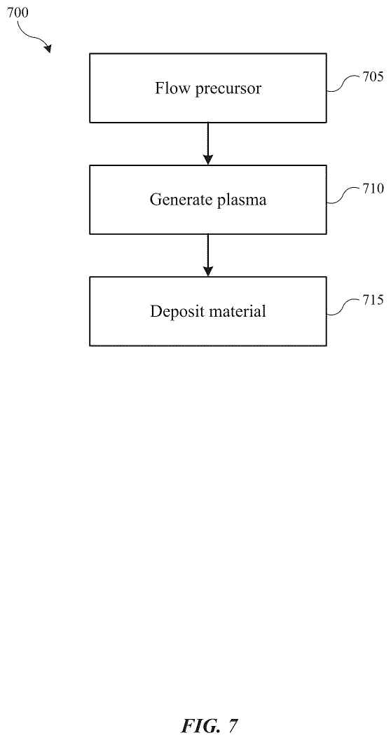

FIG. 7 shows operations of an exemplary method 700 of substrate processing according to some embodiments of the present technology. The method may be performed in a variety of processing chambers, including processing system 200 described above, which may include diffusers according to embodiments of the present technology, such as diffuser 300 or 500. Method 700 may include a number of optional operations, which may or may not be specifically associated with some embodiments of methods according to the present technology.

Method 700 may include a processing method that may include operations for forming a hardmask film or other deposition operations. The method may include optional operations prior to initiation of method 700, or the method may include additional operations. For example, method 700 may include operations performed in different orders than illustrated. In some embodiments, method 700 may include flowing one or more precursors into a processing chamber at operation 705. For example, the precursor may be flowed into a chamber, such as included in system 200, and may flow the precursor through one or more of a gasbox, a blocker plate, or a diffuser, prior to delivering the precursor into a processing region of the chamber.

In some embodiments, the diffuser may be characterized by a first surface and a second surface, and may define a number of apertures through a thickness of the diffuser. Any of the other characteristics of diffusers described previously may also be included, including any aspect of diffuser 300 or 500, such as that the second surface may be anodized while the first surface remains un-anodized. In some embodiments, each aperture may include an upper region and a lower region, which may be separated by a choke region. The upper region may be un-anodized, the lower region may be anodized, and the choke region may be un-anodized or anodized. In some embodiments, the lower region may have a generally conical profile shape. At operation 710, a plasma may be generated of the precursors within the processing region, such as by providing RF power to the diffuser to generate a plasma. Material formed in the plasma may be deposited on the substrate, such as a glass and/or semiconductor substrate, at operation 715. In some embodiments, depending on the thickness of the material deposited, the deposited material may be characterized by a thickness at the edge of the substrate that approximately the same as a thickness within a central region of the substrate. For example, the material deposited is characterized by a thickness proximate an edge of the substrate has a target uniformity of less than 500 A.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A diffuser for a substrate processing chamber, comprising:
a diffuser body that is characterized by a first surface on an inlet side of the diffuser body and a second surface on an outlet side of the diffuser body, wherein:
the diffuser body defines a plurality of apertures through a thickness of the diffuser body;
the first surface is un-anodized; and
the second surface is anodized.

2. The diffuser for a substrate processing chamber of claim 1, wherein:
each of the plurality of apertures comprises an upper region and a lower region; and
the upper region and the lower region are separated by a choke region.

3. The diffuser for a substrate processing chamber of claim 2, wherein:
the choke region is anodized.

4. The diffuser for a substrate processing chamber of claim 2, wherein:
the choke region is un-anodized.

5. The diffuser for a substrate processing chamber of claim 2, wherein:
the lower region is anodized.

6. The diffuser for a substrate processing chamber of claim 2, wherein:
the lower region comprises a generally conical shape.

7. The diffuser for a substrate processing chamber of claim 1, wherein:
the diffuser body comprises a lateral surface that extends between and couples the first surface and the second surface; and
the lateral surface is un-anodized.

8. A method of anodizing one surface of a diffuser, comprising:
coating a first surface of a diffuser with a polymeric material while leaving a second surface of the diffuser exposed, wherein:
the first surface is opposite the second surface; and
the diffuser defines a plurality of apertures through a thickness of the diffuser
applying heat to the diffuser;
exposing the diffuser to a chemical bath;
applying voltage to the chemical bath to anodize the second surface of the diffuser; and
removing the polymeric material from the first surface.

9. The method of anodizing one surface of a diffuser of claim 8, further comprising:
flowing a pressurized material through the apertures after applying heat to the diffuser.

10. The method of anodizing one surface of a diffuser of claim 9, wherein:
flowing the pressurized material comprises one or both of bead blasting and CO₂ blasting.

11. The method of anodizing one surface of a diffuser of claim 9, wherein:
each of the plurality of apertures comprises an upper region and a lower region;
the upper region and the lower region are separated by a choke region; and
flowing the pressurized material removes any polymeric material that is present in the choke region of each of the plurality of apertures.

12. The method of anodizing one surface of a diffuser of claim 8, wherein:
coating the first surface comprises using a directional coating process to apply the polymeric material onto the first surface and into a portion of each of the plurality of apertures at an angle relative to a length of each of the plurality of apertures.

13. The method of anodizing one surface of a diffuser of claim 8, wherein:
removing the polymeric material comprises:
applying heat to the polymeric material to soften the polymeric material; and
peeling the polymeric material from the diffuser.

14. The method of anodizing one surface of a diffuser of claim 13, wherein:
removing the polymeric material further comprises exposing the diffuser to a solvent.

15. The method of anodizing one surface of a diffuser of claim 8, wherein:
applying voltage to the chemical bath comprises:
ramping up the voltage from a starting voltage to target voltage; and
maintaining the voltage at the target voltage for a predetermined period of time.

16. The method of anodizing one surface of a diffuser of claim 15, wherein:
applying voltage to the chemical bath further comprises:
ramping up the voltage from the target voltage to an additional target voltage; and
maintaining the voltage at the additional target voltage for an additional predetermined period of time.

17. The method of anodizing one surface of a diffuser of claim 8, wherein:
the diffuser comprises a lateral surface that extends between and couples the first surface and the second surface; and
the method further comprises coating the lateral surface with the polymeric material.

18. A method of processing a substrate, comprising:
flowing a precursor into a processing chamber, wherein:
the processing chamber comprises a diffuser and a substrate support on which a substrate is disposed;
a processing region of the processing chamber is at least partially defined between the diffuser and the substrate support;
the diffuser is characterized by a first surface and a second surface facing the substrate support and being opposite the first surface;
the diffuser defines a plurality of apertures through a thickness of the diffuser;
the first surface is un-anodized; and
the second surface is anodized;
generating a plasma of the precursor within the processing region of the processing chamber; and
depositing a material on the substrate.

19. The method of processing a substrate of claim 18, wherein:
each of the plurality of apertures comprises an upper region and a lower region;
the upper region and the lower region are separated by a choke region; and
the choke region is un-anodized.

20. The method of processing a substrate of claim 19, wherein:
the lower region comprises a generally conical shape.
